(19) United States
(12) Patent Application Publication
(10) Pub. No.: US 2025/0146123 A1
(43) Pub. Date: May 8, 2025

(54) VAPOR SOURCE, NOZZLE, AND METHOD OF DEPOSITING AN EVAPORATED MATERIAL ON A SUBSTRATE

(71) Applicant: Applied Materials, Inc., Santa Clara, CA (US)

(72) Inventors: Julian AULBACH, Alzenau (DE); Andreas MÜLLER, Karlstein (DE); Andreas LOPP, Freigericht (DE)

(21) Appl. No.: 18/867,897

(22) PCT Filed: Jul. 5, 2022
(86) PCT No.: PCT/IB2022/056210

§ 371 Date: Nov. 21, 2024

(51) Int. Cl. C23C 14/24

(52) U.S. Cl. CPC C23C 14/24

(57) ABSTRACT

A vapor source for depositing an evaporated material on a substrate is provided. The vapor source includes a vapor distribution pipe with a plurality of nozzles, wherein at least one nozzle of the plurality of nozzles includes a nozzle body with a nozzle channel extending along a nozzle axis for releasing evaporated material through a nozzle orifice; and a shielding portion connected to and in thermal contact with the nozzle body, the shielding portion having an aperture for passage of a low-angle part of the evaporated material toward a substrate. At least one lateral opening is provided between the shielding portion and the nozzle body for passage of a high-angle part of the evaporated material, particularly toward a wall of a material collector. Further described are a nozzle for a vapor source and a method of depositing an evaporated material on a substrate.

### TECHNICAL FIELD

Embodiments of the present disclosure relate to apparatuses and methods for directing an evaporated material toward a substrate in a vacuum chamber of a vacuum deposition system. Specifically, embodiments of the present disclosure relate to a vapor source with a plurality of nozzles for directing the evaporated material, e.g. an organic material, toward a substrate for depositing the material on the substrate. Further embodiments relate to nozzles for a vapor source, to vacuum deposition systems with a vapor source, and to methods for depositing an evaporated material on a substrate in a vacuum chamber. Embodiments particularly relate to the deposition of a pixel pattern on a substrate and to deposition sources and systems used in the manufacture of organic light-emitting diode (OLED) devices.

### BACKGROUND

Techniques for layer deposition on a substrate include, for example, thermal evaporation, physical vapor deposition (PVD), and chemical vapor deposition (CVD). Coated substrates may be used in several applications and in several technical fields. For instance, coated substrates may be used in the field of organic light emitting diode (OLED) devices. OLEDs can be used in the manufacture of television screens, computer monitors, mobile phones, other hand-held devices, and the like for displaying information. An OLED device, such as an OLED display, may include one or more layers of an organic material situated between two electrodes that are all deposited on a substrate.

During deposition, the substrate can be supported on a carrier that carries the substrate, for example in a vertical orientation. The vapor from a vapor source may be directed toward the substrate through a mask, e.g. a fine metal mask (FMM) or a mask layer provided on the substrate, to create a patterned film on the substrate. One or more materials may be deposited on the substrate to create small pixels that can be addressed individually to create functional devices such as full color displays. It is beneficial for the display quality to create clearly defined pixels having nearly vertical walls and a uniform thickness over the full area of the pixel. To achieve such a result, vapor molecules should beneficially not be obstructed by the edges of the mask openings (“shadowing effect”), which would result in pixels having rounded edges.

In practice this means that the vapor molecule trajectories from the nozzle onto the substrate should beneficially be normal to the plane of the substrate or lie within a defined angular range from normal, such as 30° or less. In other words, the vapor plume that is directed toward the substrate should not be strongly divergent and the vapor molecules should not hit the substrate at grazing angles, but should rather have a defined directionality corresponding to or close to the substrate normal. It is challenging to provide a nozzle that emits evaporated material at a sufficiently high rate uniformly within a directed cone around the substrate normal.

Arranging a cooled shielding device between the vapor source and the substrate may improve the deposition quality, however, the cooled shielding device needs to be regularly cleaned since material condenses and accumulates thereon, such that the up-time of the vapor source is negatively affected.

In light of the above, improved apparatuses and methods for material deposition on a substrate would be beneficial. Embodiments of the present disclosure aim at providing vapor sources, nozzles and methods for material deposition that overcome at least some of the problems mentioned above. Specifically, the deposition quality should be improved and the up-time of the system should be increased.

### SUMMARY

In light of the above, a vapor source for depositing an evaporated material on a substrate, a nozzle for directing evaporated material toward a substrate, and a method for depositing an evaporated material on a substrate are provided.

According to an aspect of the present disclosure, a vapor source for depositing an evaporated material on a substrate is provided. The vapor source includes a vapor distribution pipe with a plurality of nozzles, wherein at least one nozzle of the plurality of nozzles includes a nozzle body with a nozzle channel extending along a nozzle axis (A) for releasing evaporated material through a nozzle orifice; and a shielding portion connected to and in thermal contact with the nozzle body, the shielding portion having an aperture for passage of a low-angle part of the evaporated material toward a substrate. At least one lateral opening is provided between the shielding portion and the nozzle body for passage of a high-angle part of the evaporated material.

A “low-angle part” of the evaporated material released through the nozzle orifice may be understood as a portion of the evaporated material having trajectories along and/or close to the nozzle axis A (e.g., 30° or less relative to the nozzle axis), e.g., propagating toward the substrate within a cone centered around the nozzle axis. A “high-angle part” of the evaporated material released through the nozzle orifice may be understood as a portion of the evaporated material having trajectories with higher angles relative to the nozzle axis as compared to the low-angle part (e.g., 35° or more and 90° or less relative to the nozzle axis).

According to an aspect of the disclosure, a nozzle for directing evaporated material toward a substrate is disclosed. The nozzle includes a nozzle body with a nozzle channel extending along a nozzle axis for releasing evaporated material through a nozzle orifice; and a shielding portion connected to and in thermal contact with the nozzle body, the shielding portion having an aperture for the passage of a first part of the evaporated material toward a substrate. At least one lateral opening is provided between the shielding portion and the nozzle body for the passage of a second part of the evaporated material.

In some embodiments, the first part of the evaporated material passing through the aperture may be a low-angle part leaving the nozzle channel at low angles relative to the nozzle axis A, and the second part of the evaporated material passing through the at least one lateral opening may be a high-angle part leaving the nozzle channel at higher angles relative to the nozzle axis than the low-angle part. The aperture may be centered relative to the nozzle axis and may be arranged downstream of the nozzle orifice. In some embodiments, a third part of the evaporated material may be blocked (and optionally reflected) by the shielding portion, wherein the third part may leave the nozzle channel in an angular range between the low-angle part and the high-angle part.

According to an aspect of the disclosure, a method of depositing an evaporated material on a substrate in a vacuum chamber with a vapor source is disclosed, the vapor source including a vapor distribution pipe with a plurality of nozzles. The method includes guiding evaporated material along a nozzle axis (A) through a nozzle channel extending through a nozzle body of at least one nozzle of the plurality of nozzles and releasing the evaporated material through a nozzle orifice, wherein a low-angle part of the evaporated material released by the nozzle orifice propagates toward the substrate through an aperture of a shielding portion that is connected to and in thermal contact with the nozzle body, and a high-angle part of the evaporated material released by the nozzle orifice propagates through at least one lateral opening that is provided between the shielding portion and the nozzle body.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus. Embodiments are also directed at methods of manufacturing processed substrates, particularly coated substrates, in a vacuum deposition system described herein and substrates manufactured in accordance with the methods and/or using the systems described herein, such as OLED substrates, particularly OLED displays.

### BRIEF DESCRIPTION OF THE DRAWINGS

So that the manner in which the above recited features of the present disclosure can be understood in detail, a more particular description of the present disclosure, briefly summarized above, may be had by reference to embodiments. The accompanying drawings relate to embodiments of the present disclosure and are described in the following:

FIG. 1 shows a schematic sectional view of a part of a vapor source according to embodiments described herein;

FIG. 2 shows a perspective view of a nozzle according to embodiments described herein;

FIG. 3 shows a schematic sectional view of a part of a vapor source according to embodiments described herein;

FIG. 4 shows a schematic front view and a schematic sectional view of a material collector for a vapor source according to embodiments described herein;

FIG. 5 shows a schematic sectional view of a vacuum deposition system with a vapor source having a plurality of nozzles according to embodiments described herein;

FIG. 6 is a flow diagram illustrating a method for depositing an evaporated material on a substrate according to embodiments described herein; and

FIG. 7 is a graph illustrating the integrated intensity of evaporated material over the angle of the trajectory of the vapor molecules relative to the nozzle axis.

### DETAILED DESCRIPTION OF EMBODIMENTS

Reference will now be made in detail to the various embodiments of the present disclosure, one or more examples of which are illustrated in the figures. Within the following description of the drawings, the same reference numbers refer to the same components. Generally, only the differences with respect to individual embodiments are described. Each example is provided by way of explanation and is not meant as a limitation of the present disclosure. Features illustrated or described as part of one embodiment can be used on or in conjunction with other embodiments to yield yet a further embodiment. It is intended that the description includes such modifications and variations.

As used herein, the term “evaporated material” may be understood as a material that is evaporated and deposited on a surface of a substrate. For example, the evaporated material may be an organic material that is deposited on a substrate to form an optically active layer of an OLED device. The material may be deposited in a predetermined pattern, e.g. by using a mask (for example, a fine metal mask, FMM, that is held in front of the substrate, or a mask layer that is provided on the substrate) having a plurality of openings. A plurality of pixels may be deposited on the substrate. Other examples of evaporated material include one or more of the following: ITO, NPD, Alq₃, and metals such as silver (Ag), magnesium (Mg), lithium (Li), or ytterbium (Yb).

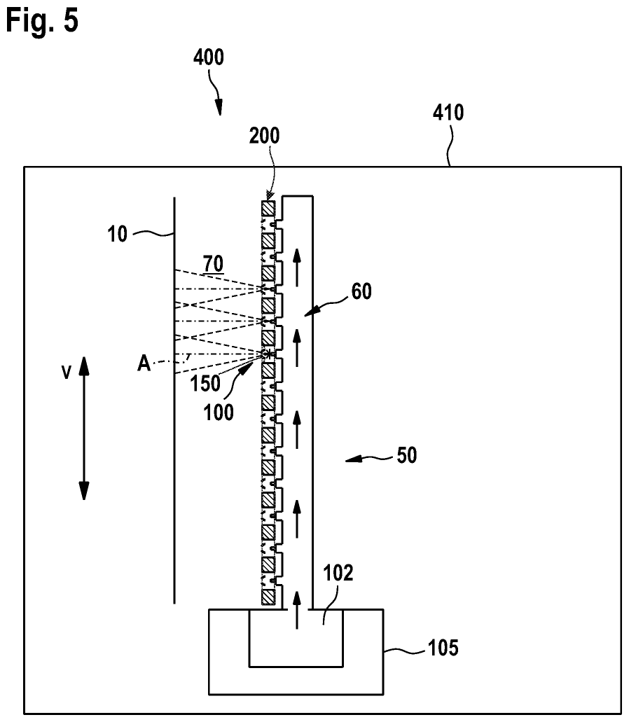

As used herein, the term “vapor source” or “evaporation source” may be understood as an arrangement providing the evaporated material to be deposited on a substrate. In particular, the vapor source may be configured to direct an evaporated material to be deposited on a substrate into a deposition area in a vacuum chamber. The evaporated material may be directed toward the substrate by a plurality of nozzles of the vapor source. The nozzles may have nozzle outlets (also referred to as “nozzle orifices” herein), respectively, which may be directed toward the deposition area, particularly toward the substrate to be coated. A vapor source 50 with a plurality of nozzles for directing evaporated material toward a substrate 10 is shown in FIG. 5 in a sectional view.

Each nozzle of the plurality of nozzles may have a nozzle channel that extends along a respective nozzle axis A toward a nozzle orifice, from which the evaporated material is released into a deposition area (typically in a vapor cone or vapor plume). If not otherwise indicated, material emission angles from the nozzle orifice are with respect to the nozzle axis A of the respective nozzle. Accordingly, low emission angles are angles close to the nozzle axis A (corresponding to vapor trajectories hitting the substrate essentially perpendicularly or within a cone close to perpendicular, see vapor cone in FIG. 5) and high emission angles are large angles relative to the nozzle axis A (corresponding to vapor trajectories having large angles relative to the substrate normal).

The present disclosure generally describes details and features of “at least one nozzle” of the plurality of nozzles of a vapor distribution pipe. However, it is to be understood that two, three, five, ten, or all the nozzles of the plurality of nozzles of the vapor source may be built and structured in a corresponding way and may have corresponding features. Specifically, all the nozzles of the vapor distribution pipe may be configured in accordance with the at least one nozzle described herein.

The vapor source may include an evaporator (or “crucible”) which heats and evaporates the material to be deposited on the substrate, and a vapor distribution pipe, which is in fluid connection with the crucible and which is configured to guide the evaporated material to the plurality of nozzles for releasing plumes of evaporated material into the deposition area in a vacuum chamber.

In some embodiments, the vapor source includes two or more distribution pipes, wherein each distribution pipe includes a plurality of nozzles. For example, each distribution pipe includes two or more nozzles, particularly ten or more nozzles, more particularly thirty or more nozzles. The nozzles of a vapor distribution pipe may be arranged in a linear array or row, such that a line source is provided. In some embodiments, the vapor source includes two or more vapor distribution pipes arranged next to each other, wherein each of the two or more vapor distribution pipes includes ten or more nozzles arranged in a row, for example three distribution pipes arranged next to each other, wherein each of the three vapor distribution pipes includes ten or more nozzles arranged in a row.

The term “vapor distribution pipe” may be understood as a tube or pipe for guiding and distributing the evaporated material. In particular, the distribution pipe may guide the evaporated material from a crucible to the plurality of nozzles which may extend through a side wall of the distribution pipe. For example, the plurality of nozzles may be mounted at openings in the vapor distribution pipe, e.g. screwed into the openings via threads. Each nozzle may include a nozzle orifice for releasing the evaporated material into a vacuum chamber toward the substrate along a main emission direction which may correspond to a nozzle axis (A), which is essentially normal to the surface of the substrate.

According to embodiments described herein, the vapor distribution pipe may be a linear distribution pipe extending in a longitudinal direction, particularly in an essentially vertical direction (V). In some embodiments, the vapor distribution pipe may include a pipe having a sectional shape of a cylinder. The cylinder may have a circular bottom shape or another suitable bottom shape, e.g. an essentially triangular bottom shape. In particular, the vapor distribution pipe may have an essentially triangular sectional shape.

The term “reflected”, e.g. “evaporated material is reflected from a surface”, describes the process of particles of evaporated material being adsorbed on a hot surface and eventually desorbed from the surface. The distribution profile of a desorption process is symmetrically centered around the surface normal and thus the evaporated material is predominantly reflected at a surface into the direction of the surface normal of the surface. The desorption rate is dependent on the temperature of the surface. The ratio of adsorption to desorption is dependent on the temperature and, by adjusting the temperature of the surface, the ratio of adsorption to desorption can be adjusted.

In some embodiments, the vapor source may include two or three vapor distribution pipes which extend in an essentially vertical direction (V), respectively. Each distribution pipe may be in fluid connection with a respective crucible such that different materials can be co-deposited on the substrate. Nozzles of a first vapor distribution pipe and nozzles of an adjacent second vapor distribution pipe may be arranged close to each other, e.g. at a distance of 5 cm or less, enabling a uniform co-deposition of two or more materials on the substrate.

According to embodiments described herein, the at least one nozzle for directing evaporated material toward a substrate includes a nozzle body with a nozzle channel extending along a nozzle axis for releasing evaporated material through a nozzle orifice, and a shielding portion connected to and in thermal contact with the nozzle body. The shielding portion provides an aperture for the passage of a first angular part of the evaporated material toward the substrate (particularly of a low-angle part of the released evaporated material), and at least one lateral opening is provided between the shielding portion and the nozzle body for the passage of a second angular part of the evaporated material (particularly of a high-angle part of the released evaporated material).

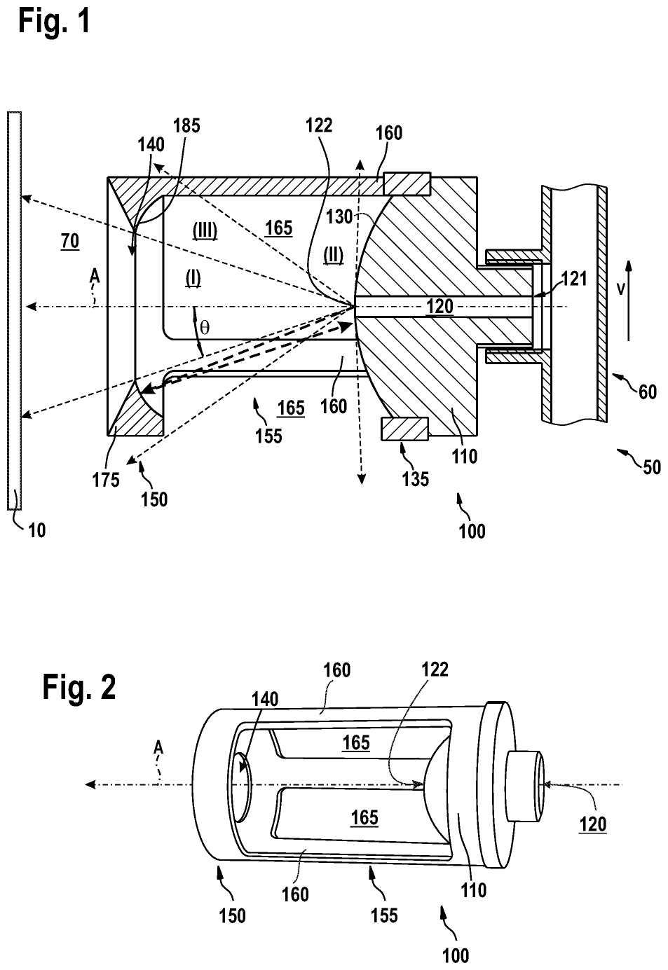

FIG. 1 is a schematic sectional view of a part of a vapor source 50 for depositing an evaporated material on a substrate 10 according to embodiments described herein. The whole vapor source 50 is depicted in FIG. 5.

The vapor source 50 includes a vapor distribution pipe 60 which may extend in an essentially vertical direction V. Alternatively, the vapor distribution pipe may extend in another direction, e.g. an essentially horizontal direction. In the embodiment depicted in FIGS. 1 and 5, the vapor distribution pipe 60 provides an essentially vertical line source. An essentially vertically extending vapor distribution pipe 60 may be beneficial because the footprint of the system can be reduced, and a compact and space-saving deposition system can be provided.

In some embodiments, the vapor source 50 includes two or more vapor distribution pipes which are supported on a common support. In some embodiments, the vapor source may be movable. In other embodiments, the vapor source may be stationary and the substrate may be movable past the vapor source. The vapor distribution pipe(s) of the vapor source may extend in an essentially vertical direction. “Essentially vertical” as used herein refers to a direction corresponding to the direction of gravity or having a deviation angle of 15° or less from the direction of gravity.

The vapor distribution pipe 60 includes a plurality of nozzles for directing the evaporated material toward the substrate 10. Specifically, the plurality of nozzles allows the evaporated material to be directed from an interior space of the vapor distribution pipe 60 into a deposition area 70 in a vacuum chamber where the substrate 10 is arranged. In some embodiments, ten or more nozzles, particularly thirty or more nozzles may be provided at the vapor distribution pipe 60. The plurality of nozzles may be arranged along the longitudinal direction of the vapor distribution pipe 60, e.g. one above the other, in a line setup (see FIG. 5 for further details in this respect).

In FIG. 1, at least one nozzle 100 of the plurality of nozzles is shown in a sectional view in detail. FIG. 2 shows a perspective view of the at least one nozzle 100. The other nozzles of the plurality of nozzles may be configured in a similar or in a corresponding way. The at least one nozzle 100 includes a nozzle body 110 with a nozzle channel 120 that extends through the nozzle body 110 along a nozzle axis A from a nozzle inlet 121 to a nozzle orifice 122. Evaporated material from the vapor distribution pipe 60 can enter the nozzle channel 120 at the nozzle inlet 121. The evaporated material can stream through the nozzle channel 120 along the nozzle axis A toward the nozzle orifice 122, and the evaporated material can exit the nozzle channel 120 through the nozzle orifice 122. The nozzle orifice 122 may be configured to emit a vapor plume of evaporated material into the deposition area 70, as it is schematically depicted in FIG. 1.

According to the embodiments described herein, the at least one nozzle 100 further includes a shielding portion 150 that is connected to and in thermal contact with the nozzle body 110. The shielding portion 150 includes an aperture 140 for the passage of a first angular part (low-angle part (I)) of the evaporated material released by the nozzle orifice 122 toward the substrate 10. A second part (high-angle part (II)) of the evaporated material released by the nozzle orifice 122 can pass through at least one lateral opening 165 that is provided between the nozzle body 110 and the shielding portion 150. The second part may laterally exit the nozzle, without propagating further toward the substrate. Accordingly, highly divergent vapor molecules which would negatively affect the deposition quality are not used for coating the substrate. Optionally, a third angular part (III) of the evaporated material, particularly in an angular range between the first and second parts, may be blocked and/or reflected by the shielding portion 150. “High-angle part” as used herein may mean that the respective vapor trajectories generally have larger angles relative to the nozzle axis A than the trajectories of the “low-angle part”.

Since the shielding portion 150 is in thermal contact with the nozzle body 110, the shielding portion 150 can be heated together with the nozzle body 110, such that condensation and accumulation of evaporated material on the shielding portion 150 during the operation of the nozzle can be reduced or avoided. In some embodiments, the evaporated material may be back-reflected and/or scattered from the shielding portion when blocked by the shielding portion. In particular, the nozzle body 110 is typically maintained at a temperature above the condensation temperature of the evaporated material during the operation of the nozzle, in order to avoid a condensation of the evaporated material inside the nozzle channel 120 which would clog the nozzle channel. If the shielding portion 150 is fixed at and in thermal contact with the nozzle body 110, the nozzle body 110 can heat the shielding portion 150 to a temperature above the condensation temperature. Since the evaporated material does not accumulate on the shielding portion 150, it is typically not necessary to regularly clean the shielding portion 150. The up-time of the system can be increased, and idle times of the system for an exchange or cleaning of the shielding portion can be reduced or avoided. Further, no separate heater may be needed for heating the shielding portion, when the shielding portion is connected to and in thermal contact with the nozzle body 110, since the shielding portion is heated together with the nozzle body, particularly via thermal contact with the heated distribution pipe.

The shielding portion 150 may be made of a thermally conductive material, e.g., a metal, and the shielding portion 150 may be connected to the nozzle body 110 by a holding portion 155 made of a thermally conductive material, e.g., a metal, such as to be in thermal contact with the nozzle body. Also the nozzle body 110, particularly the whole nozzle, may be made of a thermally conductive material, e.g., a metal, enabling a heating of the nozzle, including the shielding portion, by contact with the vapor distribution pipe 60, which is typically heated.

The shielding portion 150 with the aperture 140 may be arranged downstream of the nozzle orifice 122, such that the plume of evaporated material emitted by the nozzle orifice 122 can be shaped by the aperture 140 of the shielding portion 150 and the directionality of the vapor plume propagating toward the substrate can be improved. Specifically, vapor molecules propagating along trajectories with a divergence angle above a first maximum divergence angle θ that is defined by the aperture opening cannot propagate through the aperture 140 and are blocked by the shielding portion 150 and/or pass through the at least one lateral opening 165, e.g. toward a material dump or material collector. An “aperture” may be understood as an opening that is surrounded by a shielding wall of the shielding portion 150, such that evaporated material that impinges on the shielding wall (due to an emission angle relative to the nozzle axis A above the first maximum divergence angle) is blocked and does not propagate further toward the substrate. A low-angle part of the evaporated material propagating close to the nozzle axis A can pass through the aperture toward the substrate. Evaporated material released at higher angles relative to the nozzle axis, which would deteriorate the deposition quality, cannot propagate through the aperture 140 and is blocked by the shielding portion 150 or passes through the at least one lateral opening 165.

The deposition quality can be improved, because the plume of evaporated material released by the nozzle orifice is shaped by the aperture 140 of the shielding portion 150, and only evaporated material with trajectories in a defined angular range relative to the nozzle axis A (low-angle trajectories) is allowed to pass onto the substrate through the aperture 140.

As compared to a cold shielding device between the nozzle and the substrate for shaping the emitted vapor plume, the shielding portion of the at least one nozzle according to embodiments described herein is in thermal contact with the nozzle body and therefore heated during operation of the nozzle, such that cleaning of the shielding portion may not be necessary at regular intervals, and the up-time of the system can be increased. For example, the nozzle 100 with the shielding portion 150 can be operated without clogging for 500 hours or more, particularly 1000 hours or more, or even 2000 hours or more.

As compared to a “shaping nozzle” with a circumferentially closed shaping cavity for vapor plume shaping, the shielding portion 150 of the at least one nozzle according to embodiments described herein is held downstream of the nozzle orifice with the at least one lateral opening between the nozzle body and the shielding portion, such that a high-angle part of the released evaporated material can laterally exit the nozzle and does not propagate further toward the substrate. Removing the high-angle part laterally from the nozzle is beneficial, because the high-angle part may negatively affect the deposition quality, causing a shadowing effect and impairing the deposition uniformity.

According to some embodiments described herein, a first part of the evaporated material released by the nozzle orifice (low-angle part) is allowed to pass through the aperture 140 toward the substrate for coating the substrate. A second part of the evaporated material released by the nozzle orifice (high-angle part) passes through the at least one lateral opening 165 and exits the nozzle laterally, e.g., propagating toward a material collector. A third part of the evaporated material released by the nozzle orifice, particularly having angles in a range between the first part and the second part, may impinge on a shielding surface 185 of the shielding portion 150 and may optionally be scattered and/or back-reflected by the shielding portion back toward the nozzle body. Optionally, a front surface 130 of the nozzle body 110 may then scatter and/or reflect the third part at least partially in a direction through the at least one lateral opening 165, e.g., toward a material collector.

In some embodiments, the nozzle body 110 may include a front surface 130 that surrounds the nozzle orifice 122 and/or faces toward the shielding portion 150. The front surface 130 can optionally be shaped such that evaporated material impacting on the front surface 130 is predominantly reflected away from the nozzle axis A, particularly through the at least one lateral opening 165. In some embodiments, the front surface 130 is at least one of curved, convex and formed as a section of a spherical surface, particularly of a sphere substantially centered on the nozzle axis A.

In some embodiments, which can be combined with other embodiments described herein, the shielding portion 150 includes a ring body 175 that defines the aperture 140 (circumferentially surrounding the aperture 140 and defining the aperture diameter D₁) and is arranged downstream of the nozzle orifice 122 and centered with respect to the nozzle axis A. The ring body 175 may surround the aperture 140 like an annulus, as it is schematically depicted in the perspective view of FIG. 2. In particular, the ring body 175 may circularly surround and define the aperture 140, which may be a circular aperture. The nozzle axis A may run through the center of the circular aperture, such that essentially a cone of evaporated material starting from the nozzle orifice 122 can propagate through the aperture 140. The cone that is defined by the nozzle orifice 122 and the aperture 140 may have an apex angle corresponding to the first maximum divergence angle θ, which means that (only) evaporated material propagating at angles θ or less from the nozzle orifice 122 relative to the nozzle axis A passes through the aperture 140. In some embodiments, 0 may be 40° or less, particularly 30° or less, more particularly 20° or less, or even less than 20°.

In some embodiments, which can be combined with other embodiments described herein, the aperture 140 is circular and provides a cone angle (=first maximum divergence angle θ) with respect to the nozzle orifice 122 of 10° or more and 60° or less, particularly 20° or more and 40° or less, for the passage of the low-angle part of the evaporated material toward the substrate 10.

In some embodiments, which can be combined with other embodiments described herein, the ring body 175 has a shielding surface 185 that may be directed toward the nozzle orifice 122. The shielding surface 185 may block evaporated material impinging thereon. The shielding surface 185 may be above the condensation temperature of the evaporated material during the operation of the nozzle, such that evaporated material impinging thereon does not accumulate thereon. In some implementations, the shielding surface 185 is formed to scatter and/or back-reflect evaporated material hitting the shielding surface 185, particularly toward the nozzle body, e.g., toward the front surface 130 of the nozzle body and/or back toward the nozzle orifice 122.

In some embodiments, the shielding surface 185 of the shielding portion 150 may be curved and/or concave, particularly facilitating a back-reflection of material essentially into the incoming direction. In particular, the shielding surface 185 may be formed as a section of a spherical surface, particularly of a sphere that is substantially centered at the nozzle axis, e.g., centered at the nozzle orifice 122. A back-reflection of evaporated material in a direction toward the front surface 130 of the nozzle body 110, is facilitated. The material may subsequently be reflected from the front surface 130 of the nozzle body, and may optionally laterally exit the nozzle through the at least one lateral opening 165.

In some embodiments, which can be combined with other embodiments described herein, the shielding portion 150 is connected to the nozzle body 110 by a holding portion 155 that is connected to, particularly attached to the nozzle body 110. The holding portion 155 may be configured to hold the shielding portion 150 in thermal contact with the nozzle body 110 at a position in front of the nozzle orifice 122. For example, the holding portion 155 may include one or more support bars 160 for holding the shielding portion at a position downstream of the nozzle orifice 122 spaced-apart therefrom. As is schematically depicted in FIG. 2, the holding portion 155 may include three support bars 160 that hold the shielding portion 150 at a position downstream of and spaced-apart from the nozzle orifice 122. The one or more support bars 160 may extend essentially parallel to the nozzle axis A and may be provided at different positions of a circumference of the nozzle body for reliably holding the shielding portion at a position centered with respect to the nozzle axis A. Specifically, the shielding portion 150 may be formed as a ring body 175, and two, three or more support bars 160 may extend from a circumference of the ring body 175 toward the nozzle body 110 to be connected with the nozzle body 110 at a joining section 135 of the nozzle body 110. The joining section 135 of the nozzle body 110 may optionally be provided at an outer circumference of the nozzle body 110 and/or may annularly surround the nozzle axis A.

In some implementations, the one or more support bars 160 may define therebetween the at least one lateral opening 165 that allows the evaporated material to laterally exit the nozzle, e.g. toward a material collector. In particular, two, three or more lateral openings for the passage of the high-angle part of the evaporated material may be formed between two, three or more support bars that extend essentially parallel to the nozzle axis at different positions of a circumference of the nozzle axis. In particular, each space between two neighboring support bars may correspond to a lateral opening. In the exemplary embodiment of FIG. 2, three support bars are provided to hold the shielding portion 150, and three lateral openings are formed between respective two adjacent ones of the three support bars. The ring body 175 can reliably be held in position in front of the nozzle body while maintaining a thermal contact between the ring body and the nozzle body via the holding portion.

The at least one lateral opening 165 may be arranged such that the high-angle part of the evaporated material released by the nozzle orifice 122 can pass therethrough to laterally exit the nozzle. The high-angle part may be a part of the evaporated material released by the nozzle orifice 122 with trajectories at angles of, for example 40° or more, particularly 50° or more relative to the nozzle axis A, and/or 90° or less relative to the nozzle axis.

In some embodiments, the shielding portion 150 and the holding portion 155 are integrally formed, e.g., as a one-body component, for example as a unitary metal component. Optionally, the holding portion 155 may include a holding ring which is attached to an annular joining section 135 of the nozzle body. The holding portion 155 can be attached to the nozzle body 110 by threaded fastening, by thermal expansion and subsequent shrinking, or another suitable fastening mechanism. In the depicted example, the holding portion 155 includes a holding ring that is mounted at the annular joining section 135 of the nozzle body, and the support bars of the holding portion 155 extend essentially parallel to the nozzle axis A between the holding ring and the ring body of the shielding portion.

In some embodiments, the shielding portion 150 is in thermal contact with the nozzle body 110 and is heated through thermal conduction. For example, the shielding portion 150 and/or the holding portion 155 may be made of a material having an appropriate thermal conductivity that allows a conductive heating of the shielding portion 150 via the nozzle body 110. The nozzle body 110 may typically be directly or indirectly heated during the operation of the nozzle, such that evaporated material does not condense inside the nozzle channel.

Evaporated material released by the nozzle orifice 122 may be released uniformly as a plume of evaporated material. The plume of evaporated material may be shaped by the shielding portion 150. In particular, the aperture 140 shapes the plume of evaporated material. In some embodiments, only the low-angle part of evaporated material passes through the aperture into the deposition area 70.

The evaporated material impacts on the substrate with a deviation to the surface normal. For high deviations, a shadowing effect occurs when using a mask in an evaporation process, and a slope at the edges of the deposited features is created. The shadowing effect reduces the quality of the deposited pattern, which may be an OLED pattern. By using a vapor source and a nozzle as described herein, the maximum deviation can be limited by the shielding portion and the shadowing effect can be reduced, which improves the deposition quality.

In some embodiments, the aperture may be rotationally symmetric with respect to the nozzle axis A, particularly circular with the nozzle axis extending through the circle center. The plume of evaporated material may be shaped in a rotationally symmetric way. The deviation angle of evaporated material impacting on the substrate can be controlled and limited by the aperture of the shielding portion.

The aperture 140 may be provided as a round opening in the shielding portion that is fully surrounded by the ring body, such that the vapor plume propagating through the aperture 140 is shaped circumferentially, particularly 2-dimensionally (e.g., in the vertical direction and in a horizontal direction perpendicular to the nozzle axis).

In some implementations, a mask (not depicted) may be arranged between the vapor source 50 and the substrate 10, wherein the mask can be provided as a mask layer on the substrate surface or can be a fine metal mask FMM with an opening pattern which defines a pixel pattern to be deposited on the substrate. For example, the mask may have 100,000 openings or more, particularly 1,000,000 openings or more.

If masks are used for depositing material on a substrate, such as in an OLED production system, the mask may be a pixel mask with pixel openings having the size of about 50 μm×50 μm, or less. In one example, the pixel mask may have a thickness of about 40 μm. During the evaporation, the mask and the substrate 10 are typically in contact. Yet, considering the thickness of the mask and the size of the pixel openings, a shadowing effect may appear where the walls surrounding the pixel openings shadow an outer part of the pixel openings. The nozzles as described herein may limit the maximum angle of impact of the evaporated material on the masks and on the substrates and reduce the shadowing effect.

According to some embodiments described herein, the substrate may be coated with a material in an essentially vertical orientation. Typically, the distribution pipes are configured as line sources extending essentially vertically. In embodiments described herein, which can be combined with other embodiments described herein, the term “vertically” is understood, particularly when referring to the substrate orientation or the extension direction of the distribution pipe, to allow for a deviation from the vertical direction of 15° or less, e.g. of 10° or less. A deviation from the direction of gravity can be provided because a substrate arranged with some deviation from a vertical orientation might result in a more stable deposition process. The surface of the substrate is coated by a line source extending in one direction corresponding to one substrate dimension and by providing a translational movement of the substrate past the line source along another direction corresponding to the other substrate dimension.

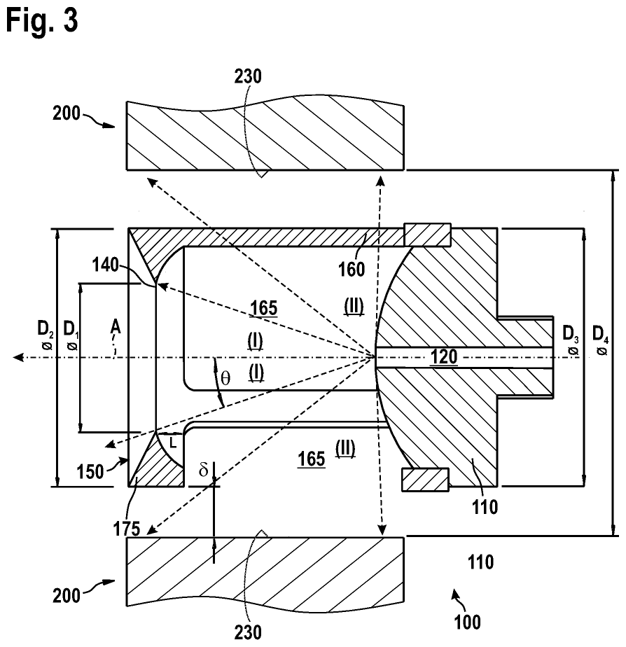

FIG. 3 shows a schematic sectional view of a part of a vapor source according to embodiments described herein. The at least one nozzle 100 of the vapor source is shown in FIG. 3 together with a material collector 200 that is arranged behind the at least one lateral opening 165 of the at least one nozzle 100. The at least one nozzle 100 shown in FIG. 3 essentially corresponds to the nozzle depicted in FIG. 1 and FIG. 2, such that reference can be made to the above explanations, which are not repeated here.

In some embodiments, the vapor source includes a material collector 200 that is arranged behind the at least one lateral opening 165 and is configured to collect the second part (=high-angle part (II)) of the evaporated material having passed through the at least one lateral opening 165. “Behind” the at least one lateral opening 165 may be understood as downstream of the at least one lateral opening 165 in the propagation direction of the evaporated material. In particular, the material collector 200 may include a wall 230 on which evaporated material impinging thereon may be adsorbed.

In some embodiments, the material collector 200 may not be thermally connected to the nozzle 100. The material collector may be provided at a distance 8 from the at least one nozzle 100, e.g., surrounding the nozzle partially or entirely in a circumferential direction. Optionally, the material collector 200 may be cooled, such that evaporated material adsorbs/adheres thereon.

In some embodiments, a cooling device is provided for cooling the material collector, such that evaporated material condenses when impinging thereon. For example, the material collector may be actively or passively cooled with a cooling medium, such as with water or a cooling gas. Specifically, cooling lines for a cooling medium may extend through the material collector. The wall 230 can be maintained at a temperature at or below the condensation temperature of the evaporated material, even if the nozzle 100 is being operated and heated.

In some embodiments, which can be combined with other embodiments described herein, the material collector may be passively cooled. For example, the material collector may be in thermal contact with another part or component that may be actively cooled, e.g., with a cooling medium, such as cooling water flowing through cooling lines. In particular, the material collector may be screwed on an actively cooled component. In some embodiments, the material collector is thermally separated from the nozzle, i.e., not in contact with the nozzle body and the shielding portion, and also not in contact with heated portions of the distribution pipe.

In some embodiments, the wall 230 of the material collector 200 may be a cylinder wall that surrounds the nozzle at least partially or entirely in a circumferential direction around the nozzle axis. In particular, the material collector 200 may provide an inner cylinder wall that (circumferentially) surrounds the area between the nozzle body and the shielding portion, where the at least one lateral opening 165 is located.

For example, the material collector 200 may include a cooled or coolable body with at least one hole (e.g., a cylinder hole with a cylinder wall) provided in the body, and the wall 230 of the hole may be arranged behind the at least one lateral opening 165 for the adherence of the high-angle part (II) of the evaporated material. In some embodiments, at least a part of the nozzle 100, particularly a front part of the nozzle body 110, the holding portion 155 and/or the shielding portion 150, may at least partially protrude into a hole of the material collector 200. Therefore, the high-angle part of the evaporated material propagating through the at least one lateral opening 165 can impinge on the wall 230 of the hole and adhere thereon by adsorption.

The diameter of the hole D₄ may be larger than the diameter D₂ of the shielding portion 150 and/or larger than the diameter D₃ of the nozzle body 110, such that the shielding portion and/or the nozzle body can at least partially protrude into the hole of the material collector 200. Therefore, the lateral opening(s) may be circumferentially surrounded by the wall 230 of the hole.

The axial dimension of the material collector 200 may be such that the high-angle part (II) of the evaporated material that passes through the at least one lateral opening 165 is essentially entirely blocked by the wall 230 of the material collector, such that the high-angle part is hindered from propagation toward the substrate.

In some embodiments, which can be combined with other embodiments described herein, the diameter D₁ of the aperture 140 may be 5 mm or more and 30 mm or less. A distance between the nozzle body 110 and the shielding portion 150 (measured along the nozzle axis) may be 5 mm or more and 30 mm or less, particularly 10 mm or more and 20 mm or less. In some embodiments, a maximum outer diameter D₂ of the shielding portion 150 and/or a maximum outer diameter D₃ of the nozzle body 110 may be 10 mm or more and 30 mm or less, for example 15 mm or more and 25 mm or less. In some embodiments, the diameter D₂ of the shielding portion may essentially correspond to the diameter D₃ of the nozzle body. In some embodiments, the diameter D₄ of a hole in the material collector 200 into which the nozzle at least partially protrudes may be larger than D₂ and/or larger than D₃. In some embodiments, a diameter of the nozzle channel 120 may be 1 mm or more and 15 mm or less, for example between 1.5 mm and 10 mm.

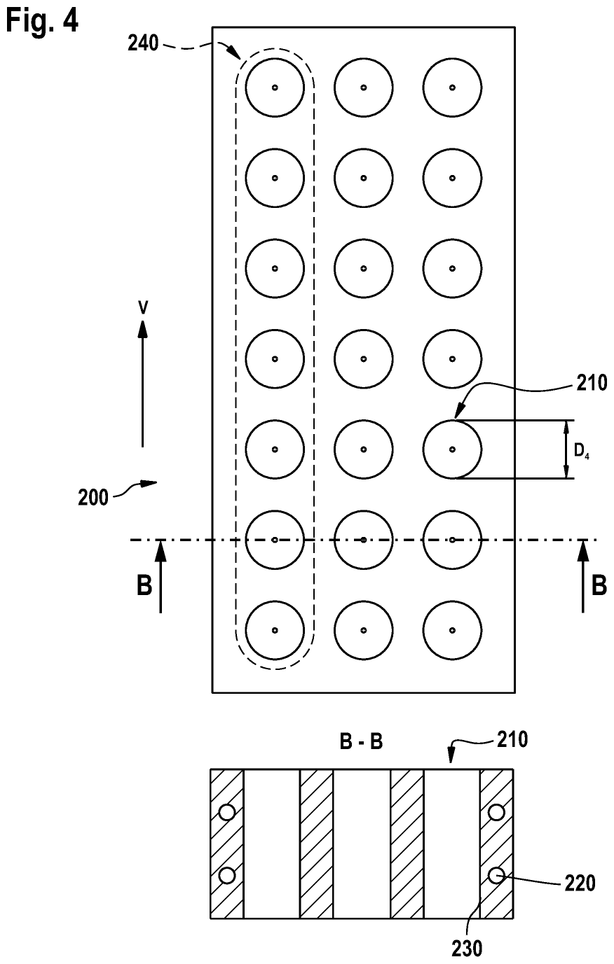

As explained above, in some embodiments, the vapor source 50 may have a plurality of nozzles, each of the plurality of nozzles being configured in accordance with the at least one nozzle 100. A material collector 200 that is configured to block the high-angle part of each of the plurality of nozzles of the vapor source is schematically depicted in FIG. 4 in a front view (upper part of FIG. 4) and in a sectional view (lower part of FIG. 4).

As is depicted in FIG. 4, the material collector 200 may include a plate with a plurality of holes 210 formed therein, wherein the holes may be through holes, particularly round or circular through holes. The plate may be coolable, e.g., via cooling lines 220 that extend through the plate. The at least one nozzle 100 may be at least partially located within one through hole of the plurality of through holes. The walls 230 of the through holes may be arranged behind the lateral openings of the nozzles, such that the high-angle parts of the evaporated material can be blocked and “collected” on the walls 230 of the through holes.

In particular, each nozzle of the plurality of nozzles may be at least partially located in a respective through hole of the plurality of through holes. The high-angle part of the evaporated material passing through the respective lateral opening of each of the nozzles can be blocked by the wall 230 of the respective hole in which the respective nozzle is located. The propagation of highly divergent vapor molecules from the plurality of nozzles toward the substrate can be reliably reduced or suppressed.

In the embodiment shown in FIG. 4, the plate has three rows 240 of holes. In one embodiment, the three rows are parallel to each other. In one embodiment, the rows 240 of holes are oriented in a vertical direction, respectively. The number of rows may correspond to the number of distribution pipes of the vapor source that are arranged next to each other. In particular, if the vapor source has one, two or three distribution pipes with a respective plurality of nozzles, the collector plate may have a corresponding number of rows of holes, into which the nozzles at least partially protrude for reducing or avoiding a grazing angle deposition on the substrate.

In some embodiments, the number of holes in each row 240 of the plate corresponds to the number of nozzles of each vapor distribution pipe 60 of the vapor source 50. One separate hole may be provided for each nozzle of each vapor distribution pipe 60, such that each nozzle 100 may at least partially protrude in an associated hole of the material collector 200. A single cooled plate with a plurality of holes may therefore be provided as a material collector 200 that individually “collects” the high-angle parts released from the nozzle orifices of the plurality of nozzles. The hole pattern in the plate may correspond to the nozzle pattern of the vapor source.

In some embodiments, the holes 210 have a circular cross section and the diameter D₄. The diameter D₄ of the holes may be larger than the diameter D₃ of the nozzle body 110 and the diameter D₂ of the shielding portion 150, e.g., by twice the distance 8. The nozzle 100 can be placed in the hole 210 such that the nozzle 100 and the wall 230 of the holes have at least the distance 8. For a nozzle 100 with a nozzle body 110 and a shielding portion 150 having a circular cross section, the distance 8 can be a circumferential gap. In particular, the nozzle can be arranged concentrically in the hole 210.

In another embodiment, the material collector can be formed for each nozzle separately. For example, each nozzle may be at least partially surrounded by a respective cylindrical sleeve. A material collector can then be installed for each nozzle separately.

In some embodiments, the material collector is cooled with a coolant. The material collector 200 may have cooling lines 220 formed therein. A suitable cooling medium can be used. In one embodiment, water is implemented as the cooling medium. In some embodiments, which can be combined with other embodiments described herein, the vapor source comprises two or more vapor distribution pipes, particularly three vapor distribution pipes, which are arranged adjacent to each other. Each of the two or more vapor distribution pipes may include ten, twenty or more nozzles arranged in a row, particularly in a vertical row for providing an essentially vertically extending line source. Each nozzle of the vapor source may be configured in accordance with the at least one nozzle 100 described herein. Particularly, each nozzle may include a shielding portion with an aperture centered at the nozzle axis and at least one lateral opening between the shielding portion and the nozzle body, such that a high-angle part of the evaporated material can laterally exit the respective nozzle. The shielding portions may be ring bodies that are respectively held downstream of a respective nozzle orifice. Since the ring bodies are thermally connected to the respective nozzle bodies, the nozzles may also be referred to as “hot ring nozzles”.

FIG. 5 is a schematic sectional view of a vacuum deposition system 400 with a vapor source 50 arranged in a vacuum chamber 410 according to embodiments described herein. The vapor source 50 has a plurality of nozzles. At least one nozzle 100 of the plurality of nozzles may be configured in accordance with any of the nozzles described herein. In particular, two, five or more nozzles provided in a vapor distribution pipe 60 of the vapor source 50 may be configured in accordance with any of the nozzles described herein.

The plurality of nozzles may have a nozzle channel, respectively, which extends along a nozzle axis A of the respective nozzle toward a deposition area 70 and defines the main emission direction of the respective nozzle. In some embodiments, the nozzle axis may extend in an essentially horizontal direction toward the substrate 10. A plurality of plumes of evaporated material can be directed from the interior space of the vapor distribution pipe 60 through the plurality of nozzles toward the substrate 10.

According to embodiments described herein, the at least one nozzle 100 has a nozzle channel 120 extending along the nozzle axis A from the nozzle inlet to the nozzle orifice and a shielding portion formed as a hot-ring body for shaping the plume of evaporated material arranged downstream of the nozzle orifice and centered with respect to the nozzle axis. At least one lateral opening for the passage of a high-angle part of the evaporated material released by the nozzle orifice is provided between the shielding portion and the nozzle body. Each nozzle of the plurality of nozzles may have a corresponding setup. In some embodiments, the vapor source may include two, three or more vapor distribution pipes arranged next to each other on a common source support, each vapor distribution pipe including a plurality of nozzles.

As is further depicted in FIG. 5, the vapor source 50 may include a source support 105, a crucible 102, and the vapor distribution pipe 60 may be supported on the source support 105. The source support 105 may optionally be movable along a source transportation path during evaporation. Alternatively, the vapor source may be a stationary source configured for coating a substrate that moves past the vapor source.

As is further depicted in FIG. 5, an optionally cooled material collector 200 may be provided for collecting the high-angle part of the evaporated material released by the nozzle orifices of the plurality of nozzles. Evaporated material may accumulate on a cooled wall of the material collector 200 during the deposition without negatively affecting the deposition quality. The shielding portion 150 (particularly, the ring body that surrounds and defines the aperture 140) that shapes the low-angle part of the evaporated material that is used for coating the substrate is hot, such that evaporated material does not (permanently) adhere thereon. Therefore, the deposition quality does not deteriorate even after a longer deposition period, since the dimensions of the shielding portion 150 do not change over time by material accumulated thereon.

The vacuum deposition system 400 may be used for various applications, including applications for OLED device manufacturing including processing methods, wherein two or more source materials such as, for instance, two or more organic materials are evaporated simultaneously. Embodiments described herein particularly relate to the deposition of organic materials, e.g. for OLED display manufacturing on large area substrates. According to some embodiments, large area substrates or carriers supporting one or more substrates may have a size of 0.5 m² or more, particularly 1 m² or more. For instance, the deposition system may be adapted for processing large area substrates, such as substrates of GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

According to another aspect, a nozzle of the vapor source according to any of the embodiments described herein is provided. The nozzle can be used as a vapor nozzle for coating a substrate by thermal evaporation in any of the vapor sources described herein.

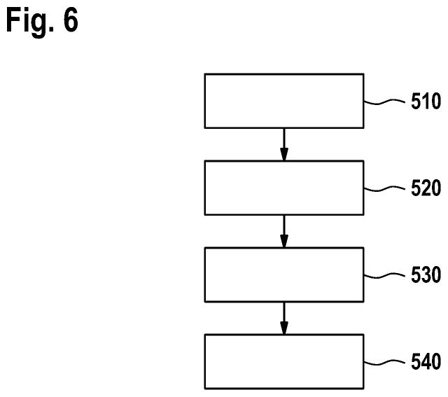

FIG. 6 is a block diagram illustrating a method of depositing an evaporated material on a substrate in a vacuum chamber according to embodiments described herein. A vapor source according to any of the embodiments described herein may be used for the deposition method. Particularly, the vapor source may include at least one vapor distribution pipe with a plurality of nozzles.

The material may be heated and evaporated in a crucible, and the evaporated material may propagate through the vapor distribution pipe and enter nozzle channels of the plurality of nozzles.

In box 510, evaporated material is guided along a nozzle axis through a nozzle channel that extends through a nozzle body of at least one nozzle of the plurality of nozzles. The nozzle channel may extend from a nozzle inlet to a nozzle orifice that is configured to release the evaporated material into a deposition area.

In box 520, the evaporated material is released through the nozzle orifice, particularly as a vapor cone or vapor plume.

In box 530, a first angular part of the evaporated material released through the nozzle orifice (particularly, a low-angle part including vapor molecules propagating close to the nozzle axis) propagates toward the substrate through an aperture of a shielding portion that is connected to and in thermal contact with the nozzle body, and a second angular part of the evaporated material released through the nozzle orifice (particularly, a high-angle part including vapor molecules propagating at higher angles relative to the nozzle axis than the low-angle part) propagates through at least one lateral opening that is provided between the shielding portion and the nozzle body. A third angular part of the evaporated material released through the nozzle orifice (particularly vapor molecules propagating at angles between the low-angle part and the high-angle part) may be blocked and optionally scattered or reflected back by the shielding portion, which may be formed as a ring body.

In box 540, the high-angle part of the evaporated material may be collected at a wall of a material collector that is arranged behind the at least one lateral opening. The low-angle part may propagate toward the substrate for coating the substrate.

In some embodiments, the material collector may be cooled, particularly actively cooled by a cooling medium. The efficiency by which evaporated material impacting on the wall of the material collector is collected can be improved.

In some embodiments, the substrate 10 is moved in front of the vapor source during the deposition of the evaporated material on the substrate.

In some embodiments, the evaporated material impinges on the substrate with an angle of 30° or less to the surface normal of the substrate.

Embodiments described herein particularly relate to the evaporation of materials on large-area substrates, e.g. for display manufacturing. For example, the substrates may be glass substrates. Embodiments described herein may also relate to semiconductor processing, e.g. for the deposition of materials, such as metals or OLED materials, on semiconductor wafers. The semiconductor wafers may be horizontally or vertically arranged during evaporation.

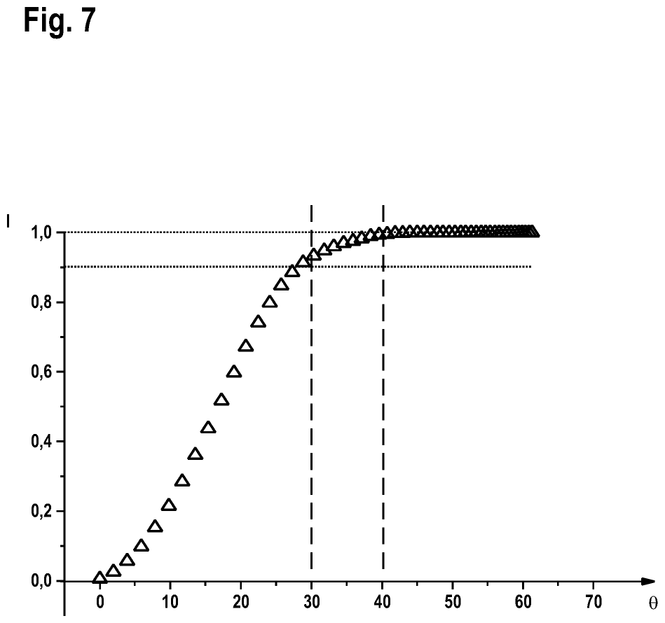

FIG. 7 shows the integrated intensity of the evaporated material at a position between the at least one nozzle 100 described herein and the substrate 10 as a function of the vapor emission angle θ relative to the nozzle axis (=the angle relative to the substrate normal). The graph illustrates that the nozzles described herein provide a vapor plume, wherein almost all of the vapor molecules (>90%) are contained in a vapor cone with an apex angle of 30°. Hardly any vapor molecules (<10%) propagate toward the substrate (and hit the substrate) at an angle above 30°, which improves the deposition quality.

According to embodiments described herein, the shielding portion with the aperture is configured such that the integrated intensity of the evaporated material downstream of the nozzle (corresponding to the low-angle part of the evaporated material that passes through the aperture) is 0.8 or more, particularly 0.9 or more, more particularly 0.95 or more at an emission angle of 30%.

This written description uses examples to disclose the disclosure, including the best mode, and also to enable any person skilled in the art to practice the described subject-matter, including making and using any devices or systems and performing any incorporated methods. While various specific embodiments have been disclosed in the foregoing, mutually non-exclusive features of the embodiments described above may be combined with each other. The patentable scope is defined by the claims, and other examples are intended to be within the scope of the claims if they have structural elements that do not differ from the literal language of the claims, or if they include equivalent structural elements with insubstantial differences from the literal language of the claims.

1. A vapor source for depositing an evaporated material on a substrate, comprising a vapor distribution pipe with a plurality of nozzles, wherein at least one nozzle of the plurality of nozzles comprises:
a nozzle body with a nozzle channel extending along a nozzle axis for releasing evaporated material through a nozzle orifice; and
a shielding portion connected to and in thermal contact with the nozzle body, the shielding portion having an aperture for passage of a low angle part of the evaporated material toward a substrate,
wherein at least one lateral opening is provided between the shielding portion and the nozzle body for passage of a high-angle part of the evaporated material.

2. The vapor source of claim 1, wherein the shielding portion comprises a ring body that defines the aperture and is arranged downstream of the nozzle orifice and centered with respect to the nozzle axis.

3. The vapor source of claim 2, wherein the ring body has a shielding surface directed toward the nozzle orifice that is configured to reflect evaporated material hitting the shielding surface.

4. The vapor source of claim 3, wherein the shielding surface is at least one of curved, concave and formed as a section of a spherical surface.

5. The vapor source of claim 1, wherein the shielding portion is connected to the nozzle body by a holding portion that is attached to the nozzle body and comprises one or more support bars for holding the shielding portion at a position downstream of the nozzle orifice.

6. The vapor source of claim 5, wherein two, three or more lateral openings for the passage of the high-angle part are formed between two, three or more support bars.

7. The vapor source of claim 5, wherein the shielding portion and the holding portion are integrally formed.

8. The vapor source of claim 1, wherein the aperture is circular and provides a cone angle with respect to the nozzle orifice of 10° or more and 60° or less for the passage of the low-angle part of the evaporated material.

9. The vapor source of claim 1, further comprising a material collector arranged behind the at least one lateral opening and configured to collect the high-angle part of the evaporated material having passed through the at least one lateral opening.

10. The vapor source of claim 9, further comprising a cooling device for cooling the material collector, such that evaporated material condenses thereon.

11. The vapor source of claim 9, wherein the material collector comprises a cylinder wall that surrounds an area between the nozzle body and the shielding portion, where the at least one lateral opening is located.

12. The vapor source of claim 9, wherein the material collector is provided as a coolable plate with a plurality of through holes, and the at least one nozzle is at least partially located within one through hole of the plurality of through holes.

13. The vapor source of claim 1, comprising two or more vapor distribution pipes arranged adjacent to each other, each of the two or more vapor distribution pipes comprising ten or more nozzles arranged in a row, each nozzle being configured in accordance with the at least one nozzle.

14. A nozzle for directing evaporated material toward a substrate, comprising:
a nozzle body with a nozzle channel extending along a nozzle axis for releasing evaporated material through a nozzle orifice; and
a shielding portion connected to and in thermal contact with the nozzle body, the shielding portion having an aperture for passage of a first angular part of the evaporated material toward a substrate,
wherein at least one lateral opening is provided between the shielding portion and the nozzle body for passage of a second angular part of the evaporated material.

15. A method of depositing an evaporated material on a substrate in a vacuum chamber with a vapor source, the vapor source comprising a vapor distribution pipe with a plurality of nozzles, the method comprising:
guiding evaporated material along a nozzle axis through a nozzle channel extending through a nozzle body of at least one nozzle and releasing the evaporated material through a nozzle orifice,
wherein a low-angle part of the evaporated material released through the nozzle orifice propagates toward the substrate through an aperture of a shielding portion that is connected to and in thermal contact with the nozzle body, and
wherein a high-angle part of the evaporated material released through the nozzle orifice propagates through at least one lateral opening that is provided between the shielding portion and the nozzle body.

16. The method of claim 15, wherein the high-angle part is collected at a wall of a material collector arranged behind the at least one lateral opening.

17. The method of claim 16, wherein the material collector is cooled.

18. The method of claim 15, wherein the substrate is moved in front of the vapor source.

19. The method of claim 15, wherein 90% or more of evaporated material impinging on the substrate has an angle of 30° or less to a surface normal of the substrate.

20. The vapor source of claim 8, wherein the aperture provides a cone angle of 20° or more and 40° or less for the passage of the low-angle part of the evaporated material.
